(19) United States
(12) Patent Application Publication
(10) Pub. No.: US 2008/0001185 A1
(43) Pub. Date: Jan. 3, 2008

(54) SEMICONDUCTOR DEVICE AND METHOD OF MANUFACTURING THE SAME

(75) Inventors: Ryo Kanda, Gunma (JP); Iwao Takahashi, Gunma (JP); Yoshinori Sato, Gunma (JP)

Correspondence Address: FISH & RICHARDSON P.C., P.O. BOX 1022, MINNEAPOLIS, MN, 55440-1022, US

(73) Assignee: SANYO ELECTRIC CO., LTD., Osaka (JP)

(21) Appl. No.: 11/770,251

(22) Filed: Jun. 28, 2007

(30) Foreign Application Priority Data
Jun. 29, 2006 (JP) 2006-179390

(51) Int. Cl. H01L 31/112

(52) U.S. Cl. 257/270

(57) ABSTRACT

In a semiconductor device, for example, a MOS transistor, of the present invention, a P type diffusion layer as a back gate region is formed in an N type epitaxial layer. An N type diffusion layer as a source region is formed in the P type diffusion layer. The P type diffusion layer is formed to have an impurity concentration peak deeper than the N type diffusion layers. This structure reduces a resistance value of a base region of a parasitic transistor, suppresses an increase in an electric potential of a base region in the MOS transistor, and thereby prevents the parasitic transistor from operating. Moreover, a breakdown voltage characteristic of the MOS transistor, which might be deteriorated by the operation of the parasitic transistor, is improved.

Priority is claimed to Japanese Patent Application Number JP2006-179390 filed on Jun. 29, 2006, the content of which is incorporated herein by reference in its entirety.

### FIELD OF THE INVENTION

The present invention relates to a semiconductor device which prevents a parasitic transistor from operating, and which improves a breakdown voltage characteristic of a semiconductor element, and relates also to a method of manufacturing the semiconductor device.

### DESCRIPTION OF THE RELATED ART

As an example of a conventional semiconductor device and a conventional method of manufacturing the semiconductor device, the following N-channel MOS transistor has been known. Firstly, an N type epitaxial layer is stacked on a P type single crystal silicon substrate. An N type drain region and a P type back gate region are formed in the epitaxial layer. An N type source region is formed in the back gate region. A gate oxide film and a gate electrode are formed on the N type epitaxial layer. The gate electrode is formed of a polysilicon film. Here, the back gate region is formed by overlapping three P type diffusion layers with one another, and thereby an appropriate threshold voltage (Vth) of the MOS transistor is achieved. In addition, the overlapping of the three P type diffusion layers increases in an impurity concentration in a deep portion of the back gate region, and thereby prevents a parasitic NPN transistor from operating. Moreover, in the step of forming the back gate region, the back gate region is formed by overlapping three P type diffusion layers with one another by means of an ion implantation technique using the gate electrode and a photoresist as a mask. This technology is described for instance in Japanese Patent Application Laid-open Publication No. 2002-314066 (Pages. 5 to 7, and FIGS. 1, 5 to 7).

As another example of the conventional semiconductor device, the following N-channel LD (Lateral Diffused) MOS transistor has been known. A P type well region is formed on an N type substrate. An N type well region is formed in the P type well region. Thereby, the substrate takes a double well structure. A P type diffusion layer, which is used as a back gate region, is formed in the P type well region and the N type well region. In addition, an N type diffusion layer, which is used as a source region, is formed in the P type diffusion layer as the back gate region. Meanwhile, another N type diffusion layer, which is used as a drain region, is formed in the N type well region. This structure achieves an appropriate threshold voltage (Vth) of the LDMOS transistor, and prevents a parasitic NPN transistor in the LDMOS transistor from operating. This technology is described for instance in Japanese Patent Application Publication No. Hei 9-139438 (Pages. 4 to 6, and FIGS. 1, 4 to 6).

As described above, in the conventional semiconductor device, a resistance value of the back gate region is reduced in order to prevent he operation of the parasitic bipolar transistor which is formed to have the back gate region of the MOS transistor as a base region. Specifically, a diffusion layer which determines the threshold voltage of the MOS transistor and a diffusion layer which reduces the resistance value of the back gate region are formed to overlap with one another in a channel region. In this structure, mask misalignment may occur during the formation of the diffusion layer which reduces the resistance value of the back gate region. For this reason, the structure has a problem that a separation distance between the gate electrodes cannot be reduced in consideration of an influence of mask misalignment. Since the separation distance cannot be reduced because of the problem, reducing the size and the on-resistance per area of the MOS transistor are difficult.

Moreover, as for the conventional semiconductor device, when the separation distance between the gate electrodes is reduced with a processing technique in the region where the diffusion layer which reduces the resistance value of the back gate region is formed, there is a case where the diffusion layer is formed in a region apart from a desired region due to the mask misalignment. In this case, an impurity concentration of the channel region changes, and this change produces a problem of changing the appropriate threshold voltage of the MOS transistor.

Furthermore, in the conventional method of manufacturing a semiconductor device, the diffusion layer which reduces the resistance value of the back gate region is formed in order to prevent the parasitic bipolar transistor in the MOS transistor from operating. By using this manufacturing method, the diffusion layer is sometimes formed in a region where the channel for the MOS transistor is formed below the gate electrodes due to the mask misalignment during the formation of the diffusion layer. In this case, it is possible to prevent the parasitic bipolar transistor from operating, but the problem of changing the threshold voltage of the MOS transistor still remains.

In addition, in the conventional method of manufacturing a semiconductor device, at the time of forming the back gate region, the diffusion layer which determines the threshold voltage of the MOS transistor and the diffusion layer which reduces the resistance value of the back gate region are formed to overlap with one another. This manufacturing method requires more manufacturing steps and more masks, and thereby has a problem that reducing the manufacturing cost is difficult.

### SUMMARY OF THE INVENTION

The present invention has been made in consideration of the above-described circumstances. A semiconductor device according to the present invention includes as follows. Specifically, the semiconductor device includes a semiconductor layer, a drain region, a source region and a back gate region, which are formed in the semiconductor layer, a gate oxide film formed on the semiconductor layer, and a gate electrode formed on the gate oxide film. In the semiconductor device, the source region is formed to overlap the back gate region, and that an impurity concentration peak of the back gate region is formed in a portion of the semiconductor layer deeper than a junction region between the back gate region and the source region. Accordingly, in the semiconductor device according to the present invention, a resistance value of the back gate region can be reduced by forming the impurity concentration peak of the back gate region in the deep portion of the semiconductor layer. This structure makes it possible to prevent a parasitic bipolar transistor in a MOS transistor from operating, and to improve a breakdown voltage characteristic of the MOS transistor.

In addition, the semiconductor device according to the present invention includes that an impurity concentration in a vicinity of a bottom surface of the source region is three times or more as high as that in a vicinity of a top surface of the source region among impurity concentrations of the back gate region in a vicinity of the junction region. Accordingly, in the semiconductor device according to the present invention, an appropriate threshold voltage of the MOS transistor is achieved, while the impurity concentration peak of the back gate region is formed in the deep portion of the semiconductor layer. This structure makes it possible to reduce the resistance value of the back gate region, and to prevent the parasitic bipolar transistor in the MOS transistor from operating.

Moreover, the semiconductor device according to the present invention includes that the gate electrode is formed of a polysilicon film and a tungsten silicon film, and the tungsten silicon film has a thickness greater than that of the polysilicon film. Accordingly, in the semiconductor device of the present invention, a diffusion layer as the back gate region is formed in a desired region by using the tungsten silicon film in the gate electrode. This structure makes it possible to reduce the device size, and to reduce the on-resistance of the MOS transistor.

In addition, the method of manufacturing a semiconductor device according to the present invention includes as follows. Specifically, the manufacturing method includes the steps of forming a gate oxide film and a gate electrode on a semiconductor layer, and then forming a back gate region in the semiconductor layer by self-alignment using the gate region and forming a source region to overlap the back gate region, and forming a drain region in the semiconductor layer. In the step of forming the back gate region, an impurity concentration peak of the back gate region is formed in a portion of the semiconductor layer deeper than a junction region between the back gate region and the source region. Accordingly, in the manufacturing method according to the present invention, the back gate region is formed in the deep portion of the semiconductor layer by self-alignment using the gate electrode. This manufacturing method makes it possible to form the back gate region in a desired region, to reduce the device size, and to reduce the on-resistance per area of an MOS transistor.

Moreover, the method of manufacturing a semiconductor device according to the present invention includes that the step of forming the back gate region includes the step of performing ion implantation at an accelerating voltage of 60 to 90 (KeV). Accordingly, in the manufacturing method according to the present invention, the back gate region is formed in the deep portion of the semiconductor layer by self-alignment using the gate electrode. This manufacturing method makes it possible to prevent a parasitic bipolar transistor in the MOS transistor from operating, and to improve a breakdown voltage characteristic of the MOS transistor.

Moreover, the method of manufacturing a semiconductor device according to the present invention includes that, in the step of forming the gate electrode, a tungsten silicon film is deposited on a polysilicon film, so that the tungsten silicon film has a thickness greater than that of the polysilicon film. Accordingly, in the manufacturing method according to the present invention, the gate electrode is formed by using the tungsten silicon film. This manufacturing method makes it possible to form the back gate region in the deep portion of the semiconductor layer by self-alignment using the gate electrode.

### BRIEF DESCRIPTION OF THE DRAWINGS

FIG. 1 is a cross-sectional view for describing a semiconductor device according to a preferred embodiment of the present invention.

FIG. 2 is a cross-sectional view for describing the semiconductor device according to this preferred embodiment of the present invention.

FIG. 3A shows impurity concentration profiles and FIG. 3B shows other impurity concentration profiles for describing the semiconductor device according to this preferred embodiment of the present invention.

FIG. 4 is a cross-sectional view for describing a method of manufacturing a semiconductor device according to this preferred embodiment of the present invention.

FIG. 5 is a cross-sectional view for describing the method of manufacturing a semiconductor device according to this preferred embodiment of the present invention.

FIG. 6 is a cross-sectional view for describing the method of manufacturing the semiconductor device according to this preferred embodiment of the present invention.

FIG. 7 is a cross-sectional view for describing the method of manufacturing a semiconductor device according to this preferred embodiment of the present invention.

FIG. 8 is a cross-sectional view for describing the method of manufacturing a semiconductor device according to this preferred embodiment of the present invention.

FIG. 9 is a cross-sectional view for describing the method of manufacturing a semiconductor device according to this preferred embodiment of the present invention.

FIG. 10 is a cross-sectional view for describing the method of manufacturing a semiconductor device according to this preferred embodiment of the present invention.

### DETAILED DESCRIPTION OF THE PREFERRED EMBODIMENTS

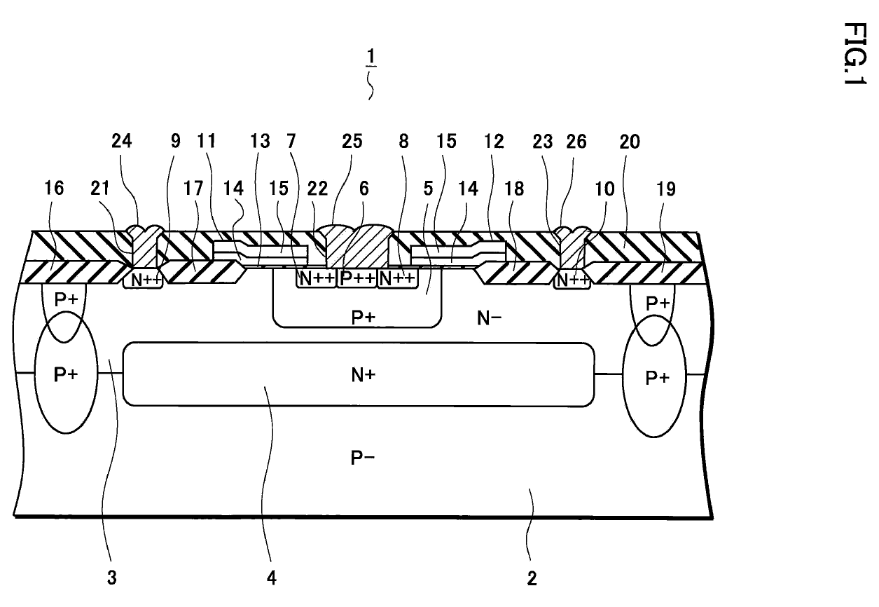

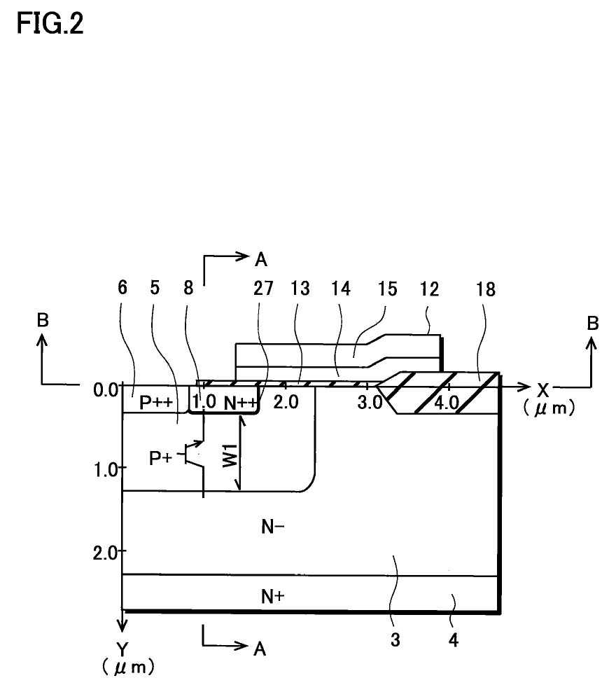

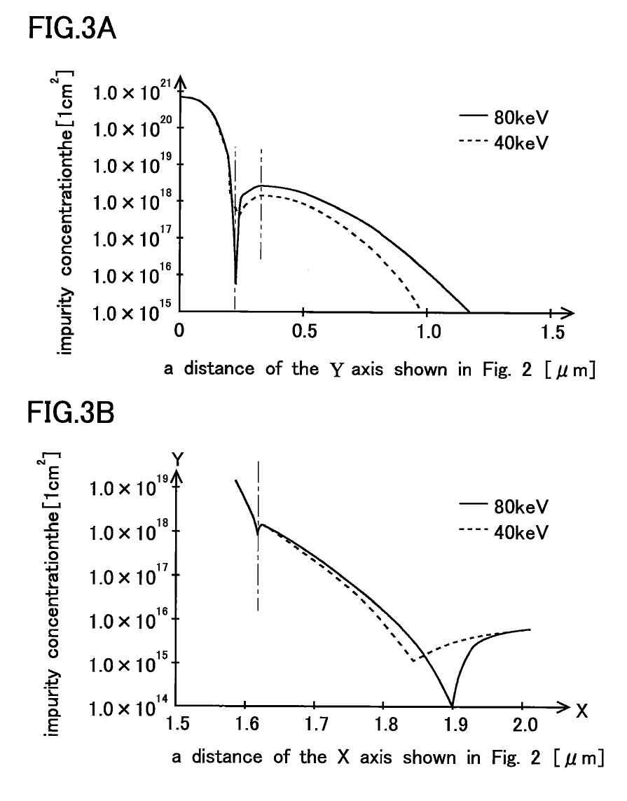

Hereinafter, descriptions will be given in detail of a semiconductor device according to a preferred embodiment of the present invention with reference to FIGS. 1 to 3. FIG. 1 is a cross-sectional view for describing the semiconductor device according to this preferred embodiment. FIG. 2 is a cross-sectional view for describing the semiconductor device according to this preferred embodiment. FIG. 3 shows impurity concentration profiles for describing the semiconductor device according to this preferred embodiment.

As shown in FIG. 1, an N-channel MOS transistor 1 mainly includes a P type single crystal silicon substrate 2, an N type epitaxial layer 3, an N type buried diffusion layer 4, P type diffusion layers 5 and 6, which are used as back gate regions, N type diffusion layers 7 and 8, which are used as source regions, N type diffusion layers 9 and 10, which are used as drain regions, and gate electrodes 11 and 12.

The N type epitaxial layer 3 is formed on the P type single crystal silicon substrate 2. Note that, although only one epitaxial layer 3 is formed on the substrate 2 in this embodiment, the preferred embodiment of the present invention is not limited to this case. For example, a plurality of epitaxial layers may be stacked on the substrate.

The N type buried diffusion layer 4 is formed on both regions of the substrate 2 and the epitaxial layer 3. As illustrated in FIG. 1, the N type buried diffusion layer 4 is formed across a region where the N-channel MOS transistor 1 is formed.

The P type diffusion layer 5 is formed in the epitaxial layer 3. The P type diffusion layer 6 is formed in the P type diffusion layer 5 in a manner of overlapping the P type diffusion layer 5. The P type diffusion layer 5 is used as the back gate region, and the P type diffusion layer 6 is used as a back gate leading region. Moreover, the P type diffusion layer 5 positioned below the gate electrodes 11 and 12 is used as a channel region. Note that, although detailed descriptions will be given later, an impurity concentration of the channel region is adjusted only by the P type diffusion layer 5, achieving an appropriate threshold voltage (Vth) of the MOS transistor 1. Furthermore, an impurity concentration in a deep portion of the back gate region is increased only by the P type diffusion layer 5, and thereby a resistance value of the back gate region is reduced.

The N type diffusion layers 7 and 8 are formed in the P type diffusion layer 5. The N type diffusion layers 7 and 8 are used as the source region. The N type diffusion layers 7 and 8, and the P type diffusion layer 6 are connected to a source electrode 25, and are equal in electric potential. Note that the N type diffusion layers 7 and 8 can be circularly formed around the P type diffusion layer 6.

The N type diffusion layers 9 and 10 are formed in the epitaxial layer 3. The N type diffusion layers 9 and 10 are used as the drain regions.

The gate electrodes 11 and 12 are formed on a gate oxide film 13. Each of the gate electrodes 11 and 12 is formed of, for example, a polysilicon film 14 and a tungsten silicon film 15 so as to have a desired thickness. Incidentally, the gate electrodes 11 and 12 can be circularly formed.

LOCOS (Local Oxidation of Silicon) oxide films 16, 17, 18 and 19 are formed in the epitaxial layer 3. The thickness of each flat portion of the LOCOS oxide films 16, 17, 18 and 19 is approximately 3000 Å to 5000 Å, for example.

An insulating layer 20 is formed over the epitaxial layer 3. The insulating layer 20 is formed of a BPSG (Boron Phospho Silicate Glass) film, a SOG (Spin On Glass) film or the like. In addition, with a known photolithography technique, contact holes 21, 22 and 23 are formed in the insulating layer 20 by dry etching using CHF₃ or CF₄ gas, for example.

In each of the contact holes 21, 22 and 23, an aluminum alloy film made of, for example, an Al—Si film, an Al—Si—Cu film or an Al—Cu film is selectively formed, so that drain electrodes 24 and 26, and the source electrode 25 are formed respectively in the contact holes 21, 22 and 23. Incidentally, the drain electrodes 24 and 26 can be circularly formed around the source electrode 25. In addition, although a layer of wiring to the gate electrodes 11 and 12 is not illustrated in the cross-section shown in FIG. 1, the gate electrodes 11 and 12 are connected to the wiring layer in other regions.

Next, descriptions will be given of a structure of the back gate region in the MOS transistor 1 and characteristics of the MOS transistor 1 with reference to the FIGS. 2 and 3. Note that the X axis shown in FIG. 2 indicates a distance (μm) apart from the P type diffusion layer 6 to the LOCOS oxide film 18. Meanwhile, the Y axis indicates a distance (μm) apart from a surface to a deep portion of the epitaxial layer 3. FIG. 3A shows impurity concentration profiles in a direction of the line A-A in the cross-sectional view shown in FIG. 2. FIG. 3B shows other impurity concentration profiles in a direction of the line B-B in the cross-sectional view shown in FIG. 2. Moreover, the impurity concentration profiles in the direction of the line B-B are of a region in a vicinity of the surface of the epitaxial layer 3.

As shown in FIG. 2, the P type diffusion layer 5, which is used as the back gate region, is formed in the N type epitaxial layer 3 of the MOS transistor 1. The N type diffusion layer 8, which is used as the source region, is formed in the P type diffusion layer 5. A PN junction region 27 is formed between the P type diffusion layer 5 and the N type diffusion layer 8 as shown by a thick line. The N type diffusion layer 8 expands to approximately 0.3 to 0.4 (μm) from the surface of the N type epitaxial layer 3. The P type diffusion layer 5 expands to approximately 1.2 to 1.4 (μm) from the surface of the N type epitaxial layer 3

As shown in FIG. 2, in the MOS transistor 1, a parasitic NPN transistor is formed with the N type diffusion layer 8 as an emitter region, the P type diffusion layer 5 as a base region, and the N type epitaxial layer 3 as a collector region.

Here, the parasitic NPN transistor comes into an ON state due to the following operations. Firstly, when the MOS transistor 1 is in the ON state, conductivity modulation occurs in the N type epitaxial layer 3 as a drain region. Free carriers (holes) are generated, which are paired up with free carriers (electrons), in the N type epitaxial layer 3 constituting a current path. Then, when the MOS transistor 1 is in an OFF state, the free carriers (holes) generated in the N type epitaxial layer 3 flow into the P type diffusion layer 5, and forward biases between the emitter and the base of the parasitic NPN transistor. Thereby the parasitic NPN transistor comes into the ON state in some cases. In other words, in a case where the resistance value of the P type diffusion layer 5 is large, the flow of the free carriers (holes) into the base region increases an electric potential of the base region, and thereby the parasitic NPN transistor is easily to be operated.

As described above, in this embodiment, the P type diffusion layer 5 expands into the deep portion of the N type epitaxial layer 3. This structure makes a base width W1 of the parasitic NPN transistor increase, and makes a resistance value of the base region decrease. Moreover, it is possible to suppress the increase in the electric potential caused by the flowing of the free carriers (holes) into the P type diffusion layer 5 when the MOS transistor 1 is in the OFF state. As a result it is possible to prevent the ON state operation of the parasitic NPN transistor, and to prevent breakdown of the MOS transistor 1 caused by the operation of the parasitic NPN transistor. That is, it is possible to improve a breakdown voltage characteristic of the MOS transistor 1.

In FIG. 3A, the solid line indicates the impurity concentration profile in a case where an accelerating voltage is applied at 80 (KeV) at the time of forming the P type diffusion layer 5. Meanwhile, the dotted line indicates the impurity concentration profile in a case where an accelerating voltage is applied at 40 (KeV) at the time of forming the P type diffusion layer 5.

In both cases of the solid line and the dotted line, the PN junction region 27 (see FIG. 2) is formed in a region (a region where each of the solid line and the dotted line intersects a dashed line) approximately 0.2 to 0.3 (μm) apart from the surface of the epitaxial layer 3 (see FIG. 2).

Specifically, a valley-shaped region of the impurity concentration profile, where each of the solid line and the dotted line intersects the dashed line, is the PN junction region 27. The valley-shape is formed because, in the PN junction region 27, a P type impurity concentration and an N type impurity concentration are compensated each other, and thereby a low impurity concentration region is formed. Then, a region on the left side of the PN junction region 27 in FIG. 3A corresponds to a region where the P type diffusion layer 5 (see FIG. 2) and the N type diffusion layer 8 (see FIG. 2) are formed as overlapped with each other, and thus this region functions as the N type diffusion layer 7. On the other hand, a region on the right side of the PN junction region 27 in FIG. 3A corresponds to a region which functions as the P type diffusion layer 5. In other words, the region on the right side of the PN junction region 27 in FIG. 3A indicates the impurity concentration profile of the P type diffusion layer 5. As shown by a chain double-dashed line, an impurity concentration peak of the P type diffusion layer 5 is formed in the deeper portion than the PN junction region 27. The impurity concentrations in a vicinity of the PN junction region 27 on the P type diffusion region 5 side are approximately 3.21×10¹⁸ (/cm²) in the case of the solid line, and 1.49×10¹⁸ (/cm²) in the case of the dotted line. Note that, although explained in a method of manufacturing a semiconductor device in detail, the difference in the impurity concentrations is caused as follows. In the structure shown by the solid line, the gate electrodes 11 and 12 are formed by using the tungsten silicon film 15, and thereby ion implantation can be performed at a highly accelerating voltage. As a result, it is possible to form the impurity concentration peak in the deep portion of the epitaxial layer 3.

In FIG. 3B, a solid line indicates the impurity concentration profile in the case where the accelerating voltage is applied at 80 (KeV) at the time of forming the P type diffusion layer 5. Meanwhile, the dotted line indicates the impurity concentration profile in a case where the accelerating voltage is applied at 40 (KeV) at the time of forming the P type diffusion layer 5

In both cases of the solid line and the dotted line, the PN junction region 27 (see FIG. 2) is formed in a region (a region where each of the solid line and the dotted line intersects the dashed line) approximately 1.6 (μm) apart from a reference point of the P type diffusion layer 6 (see FIG. 2).

Specifically, a valley-shaped region of the impurity concentration profile, where each of the solid line and the dotted line intersects the dashed line, is the PN junction region 27. The valley-shape is formed because, in the PN junction region 27, the P type impurity concentration and the N type impurity concentration are compensated each other, and thereby a low impurity concentration region is formed. Then, a region on the left side of the PN junction region 27 in FIG. 3B corresponds to a region where the P type diffusion layer 5 (see FIG. 2) and the N type diffusion layer 8 (see FIG. 2) are formed as overlapped with each other, and thus this region functions as the N type diffusion layer 8. On the other hand, a region on the right side of the PN junction region 27 in FIG. 3B corresponds to a region which functions as the P type diffusion layer 5. In other words, the region on the right side of the PN junction 27 in FIG. 3B indicates the impurity concentration profile of the P type diffusion layer 5. As illustrated, the impurity concentrations are approximately the same in both cases of the solid line and the dotted line for achieving an appropriate threshold voltage (Vth) of the MOS transistor 1. The impurity concentrations of the P type diffusion layer 5 in the channel region are approximately 1.00×10¹⁸ (/cm²) in both case of the solid line and the dotted line.

As described above, it is necessary to reduce the resistance value of the base region in order to prevent the parasitic NPN transistor from operating. On the other hand, in order to achieve the appropriate threshold voltage (Vth) of the MOS transistor 1, conditions for forming the P type diffusion layer 5, for example, an impurity concentration profile, diffusion depth, and the like, are designed. In this embodiment, when the P type diffusion layer 5 is formed, ions are implanted and thermally diffused so that the diffusion layer 5 has the impurity concentration peak in the deep portion of the N type epitaxial layer 3. Thereby, the impurity concentration of the P type diffusion layer 5 in the deep portion of the N type epitaxial layer 3 can be increased and also the impurity concentration in the channel region can be set to a desired value. As a result, by increasing the impurity concentration in the deep portion of the P type diffusion layer 5, it is possible to reduce the resistance value of base region of the parasitic NPN transistor. Moreover, it is possible to suppress the increase in the electric potential caused by the flowing of the free carriers (holes) into the P type diffusion layer 5 when the MOS transistor 1 is in the OFF state. Consequently, it is possible to prevent the ON state operation of the parasitic NPN transistor, and to prevent breakdown of the MOS transistor 1, which might be deteriorated by the operation of the parasitic NPN transistor.

In other words, the impurity concentration profile of the P type diffusion layer 5 is designed to prevent the ON state operation of the parasitic NPN transistor. Thereby, impurity concentration ratios (the line A-A direction/the line B-B direction) in the vicinity of the PN junction region 27 on the P type diffusion region 5 side are approximately 3.21 in the case of the solid line, and approximately 1.49 in the case of the dotted line. In this embodiment, the P type diffusion layer S is formed so that the impurity concentration ratio becomes larger than 3.0 or more. Thus, it is possible to prevent the ON state operation of the parasitic NPN transistor, and to improve the breakdown voltage characteristic of the MOS transistor, which might be deteriorated by the operation of the parasitic NPN transistor.

Note that, in this embodiment, the descriptions have been given of the case of the lamination structure where the gate electrodes 11 and 12 are formed of the polysilicon film 14 and the tungsten silicon film 15, but the preferred embodiment of the present invention is not limited to the above-described case. For example, a single-layer structure of the polysilicon film or the tungsten silicon film can be employed, as long as the gate electrodes 11 or 12 have a thickness enough to prevent the impurity from penetrating therethrough in the step of performing ion implantation to form the P type diffusion layer 5. Moreover, various modifications are possible to be made on the preferred embodiment of the present invention without departing from the spirit of the preferred embodiment of the present invention.

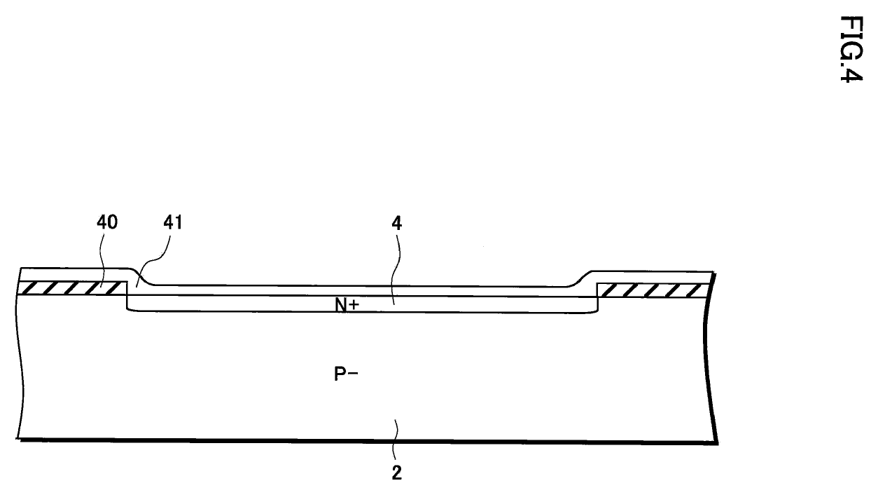

Next, descriptions will be given in detail of a method of manufacturing a semiconductor device according to another preferred embodiment of the present invention with reference to FIGS. 4 to 10. FIGS. 4 to 10 are cross-sectional views for describing the method of manufacturing a semiconductor device according to this preferred embodiment. Incidentally, in FIGS. 4 to 10, descriptions will be given of the method of manufacturing the semiconductor device shown in FIG. 1.

Firstly, as shown in FIG. 4, a P type single crystal silicon substrate 2 is prepared. A silicon oxide film 40 is formed on the substrate 2, and the silicon oxide film 40 is selectively removed, so that an opening is formed in a region where an N type buried diffusion layer 4 is to be formed. Then, by using the silicon oxide film 40 as a mask, a liquid source 41 containing an N type impurity, for example, antimony (Sb) is applied to the surface of the substrate 2 by means of a spin-coating method. Subsequently, the antimony (Sb) is thermally diffused, so that the N type buried diffusion layer 4 is formed. Thereafter, the silicon oxide film 40 and the liquid source 41 are removed.

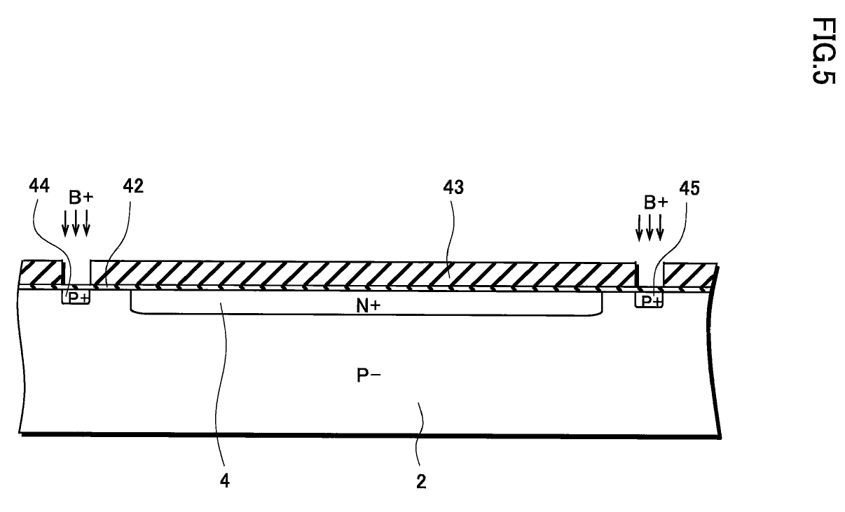

Next, as shown in FIG. 5, a silicon oxide film 42 is formed on the substrate 2, and a photoresist 43 is formed on the silicon oxide film 42. Thereafter, by means of the known photolithography technique, openings are formed in the photoresist 43 on regions where each of P type buried diffusion layers 44 and 45 are to be formed. Subsequently, ions of a P type impurity, for example, boron (B) are implanted from the surface of the substrate 2 at an accelerating voltage of 40 to 180 (keV) and a dose of 1.0×10¹³ to 1.0×10¹⁶ (/cm²). The photoresist 43 is removed, and then the P type buried diffusion layers 44 and 45 are formed by thermal diffusion. After that, the silicon oxide film 42 is removed.

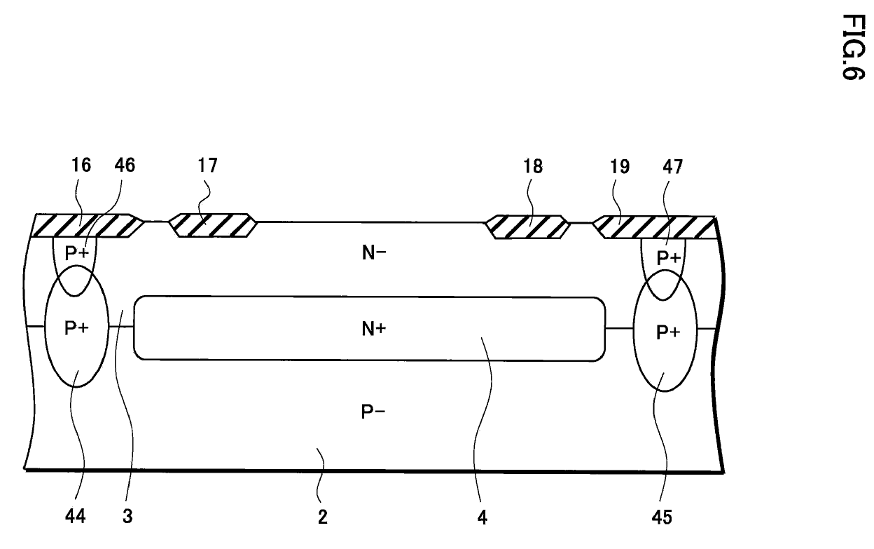

Next, as shown in FIG. 6, the substrate 2 is placed on a susceptor of a vapor phase epitaxial growth apparatus so as to form an N type epitaxial layer 3 on the substrate 2. The vapor phase epitaxial growth apparatus mainly includes a gas supply system, a reactor, an exhaust system and a control system. In this embodiment, by use of a vertical reactor, the thickness uniformity of the epitaxial layer can be improved. The N type buried diffusion layer 4 and the P type buried diffusion layers 44 and 45 are thermally diffused by heat treatment in the process of forming the epitaxial layer 3.

Next, by means of the known photolithography technique, P type diffusion layers 46 and 47 are formed in the epitaxial layer 3. Then, LOCOS oxide films 16, 17, 18 and 19 are formed in desired regions of the epitaxial layer 3.

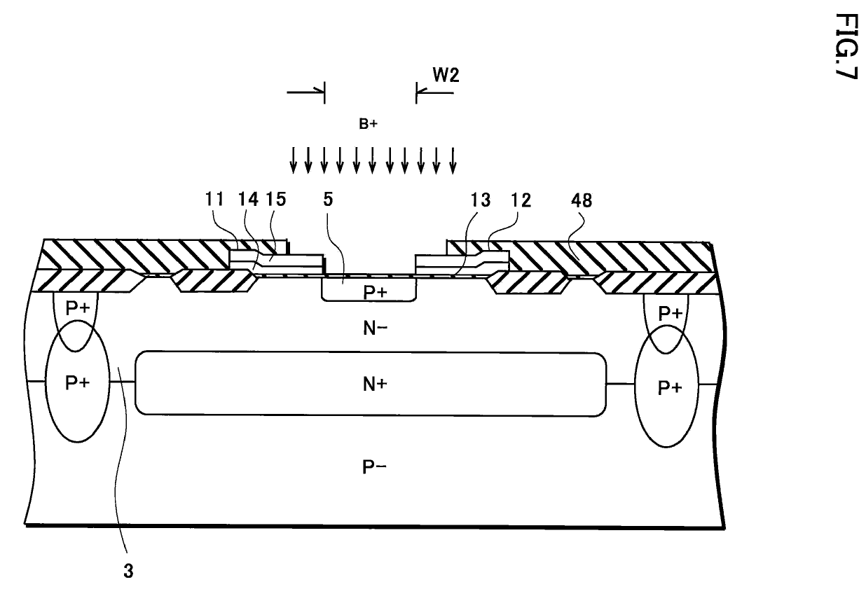

Next, as shown in FIG. 7, a silicon oxide film to be used as a gate oxide film 13 is formed on the epitaxial layer 3 so as to have a thickness of, for example, approximately 100 to 200 (Å). A polysilicon film 14 is formed on the silicon oxide film so as to have a thickness of, for example, approximately 1000 to 2000 (Å), and then a tungsten silicon film 15 is formed on the polysilicon film 14 so as to have a thickness of, for example, approximately 2000 to 3000 (Å). Thereafter, by means of the known photolithography technique, the polysilicon film 14 and the tungsten silicon film 15 are selectively removed to form gate electrodes 11 and 12.

Next, a photoresist 48 is formed on the silicon oxide film to be used as the gate oxide film 13. By means of the known photolithography technique, an opening is formed in the photoresist 48 on a region where a P type diffusion layer 5 is to be formed. Then, ions of a P type impurity, for example, boron (B) are implanted from the surface of the epitaxial layer 3 at an accelerating voltage of 60 to 90 (keV) and a dose of 1.0×10¹⁴ to 1.0×10¹⁶ (/cm²). Subsequently, the photoresist 48 is removed, and then the P type diffusion layer 5 is formed by thermal diffusion.

At this time, the P type diffusion layer 5 is formed by self-alignment using the gate electrodes 11 and 12 as a mask. As described above, since the thickness of the tungsten silicon film 15 is approximately 2000 to 3000 (Å), it is possible to prevent ions of boron (B) from being implanted into a region below the gate electrodes 11 and 12 exposed from the opening in the photoresist 48. In addition, as described by use of FIG. 2, it is possible to form the P type diffusion layer 5 having an impurity concentration peak in a deep portion of the epitaxial layer 3.

Specifically, suppose a case where the P type diffusion layer 5 is formed by an ion implantation technique using the gate electrodes 11 and 12 as a mask, each of the gate electrodes 11 and 12 is formed of only the polysilicon film 14 whose thickness is 4000 (Å). If an accelerating voltage is applied at 40 or more (KeV), the ions of boron (B) penetrate through the gate electrodes 11 and 12. On the other hand, suppose a structure in which each thickness of the gate electrodes 11 and 12 is 4000 (Å), while the thickness of the polysilicon film 14 is 1500 (Å) and that of the tungsten silicon film 15 is 2500 (Å). This structure makes it possible to prevent the ions of boron (B) from penetrating through the gate electrodes 11 and 12 even in a case where the ions of boron (B) are implanted at an accelerating voltage of 80 (KeV). In other words, by using, in the gate electrodes 11 and 12, the tungsten silicon film 15 through which the ions of boron (B) hardly penetrate, the P type diffusion layer 5 can be formed by self alignment without increasing the thickness of the gate electrodes 11 and 12.

This manufacturing method makes it possible to omit a forming step of a diffusion layer which is formed in a conventional manufacturing method for reducing a resistance value of the back gate region. In other words, it is not necessary to take account of an impurity concentration of a channel region to be disturbed by mask misalignment at the time of forming the back gate region. This allows the gate electrodes 11 and 12 to be formed with a processing technique without taking account of a degree of the mask misalignment at the time of forming the back gate region. Moreover, each cell pitch can be shortened by reducing a separation distance W2 between the gate electrodes 11 and 12, and thereby the device size can be reduced. In other words, when the back gate region is formed of only the P type diffusion layer 5, the on-resistance per area of a MOS transistor 1 can be reduced. Furthermore, by reducing the number of P type diffusion layers which constitute the back gate region, it is possible to reduce the manufacturing cost, for example, reducing the number of masks. Incidentally, the P type diffusion layer 6 as a back gate leading region is formed in the P type diffusion layer 5 in a manner of overlapping the P type diffusion layer 5 in the latter step of the manufacturing method.

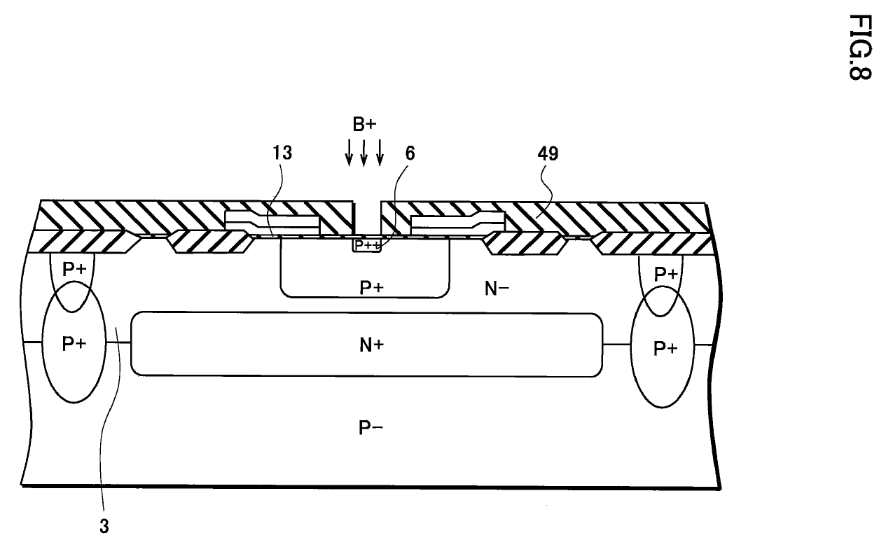

Next, as shown in FIG. 8, a photoresist 49 is formed on the silicon oxide film to be used as the gate oxide film 13. By means of the known photolithography technique, an opening is formed in the photoresist 49 on a region where a P type diffusion layer 6 is to be formed. Then, ions of a P type impurity, for example, boron (B) are implanted from the surface of the epitaxial layer 3 at an accelerating voltage of 50 to 70 (keV) and a dose of 1.0×10¹⁴ to 1.0×10¹⁶ (/cm²). Subsequently, the photoresist 49 is removed, and then the P type diffusion layer 6 is formed by thermal diffusion.

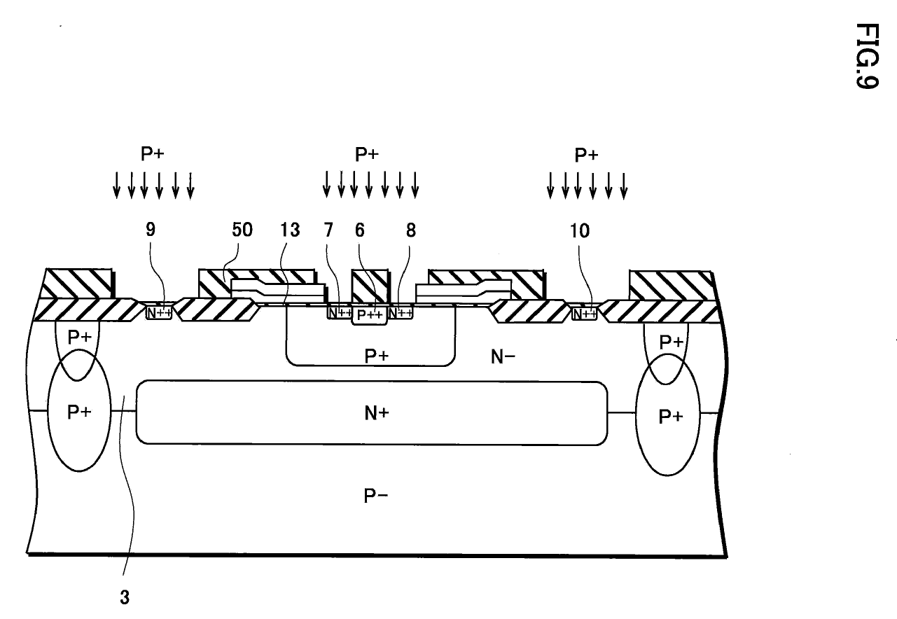

Next, as shown in FIG. 9, a photoresist 50 is formed on the silicon oxide film to be used as the gate oxide film 13. By means of the known photolithography technique, openings are formed in the photoresist 50 on regions where N type diffusion layers 7, 8, 9 and 10 are to be formed. Then, ions of an N type impurity, for example, phosphorus

(P) are implanted from the surface of the epitaxial layer 3 at an accelerating voltage of 90 to 110 (keV) and a dose of 1.0×10¹⁴ to 1.0×10¹⁶ (/cm²). Subsequently, the photoresist 50 is removed, and then the N type diffusion layers 7, 8, 9 and 10 are formed by thermal diffusion.

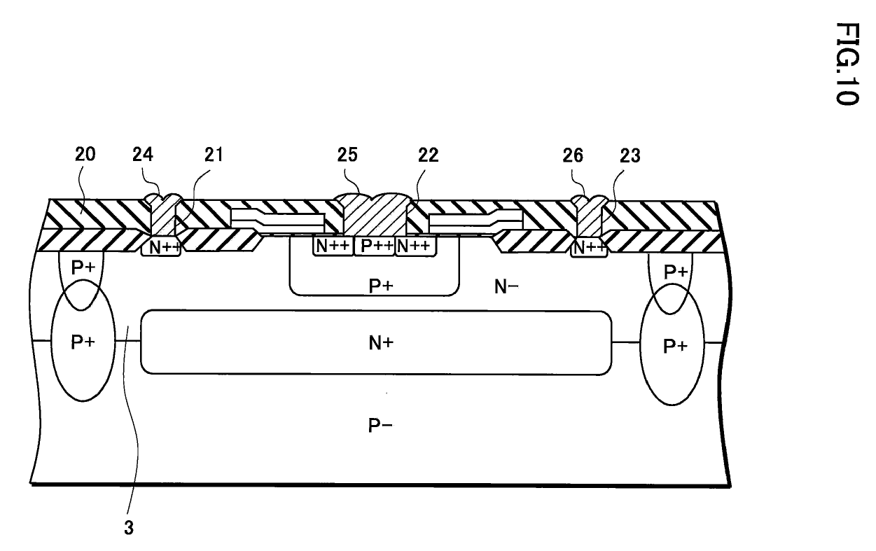

Next, as shown in FIG. 10, for example, a BPSG (Boron Phospho Silicate Glass) film, a SOG (Spin On Glass) film or the like is deposited as an insulating layer 20 over the epitaxial layer 3. Then, by means of the known photolithography technique, contact holes 21, 22 and 23 are formed in the insulating layer 20 by dry etching using CHF₃ or CF₄ gas, for example. In each of the contact holes 21, 22 and 23, an aluminum alloy film made of, for example, an Al—Si film, an Al—Si—Cu film or an Al—Cu film is selectively formed, so that drain electrodes 24 and 26 and a source electrode 25 are formed respectively in the contact holes 21, 22 and 23.

Noted that, in this embodiment descriptions have been given of the case where the accelerating voltage of 60 to 90 (KeV) is applied when the P type diffusion layer 5 is formed. However, the preferred embodiment of the present invention is not limited to the above-described case. It is only necessary that the impurity, for example, at the time of forming the P type diffusion layer 5, be prevented from penetrating through the gate electrodes. Thus, for example, the thickness of the gate electrode may allow the accelerating voltage to be applied at 90 (KeV) or more. In this case, the impurity concentration peak of the P type diffusion layer 5 is in the deep portion of the epitaxial layer and the diffusion width increases. As the result, it is possible to prevent the parasitic NPN transistor from operating. Meanwhile, descriptions have been given of the case where the gate electrodes 11 and 12 are formed of the polysilicon film and the tungsten silicon film as a two-layer structure, but the preferred embodiment of the present invention is not limited to the above-described case. The gate electrode can be formed of, for example, a polysilicon film or a tungsten silicon film as a single-layer structure. In this case, it is only necessary that the polysilicon film or the tungsten silicon film has a thickness enough to prevent implanted ions of boron (B) from penetrating through the film. Moreover, various modifications are possible to be made on the preferred embodiment of the present invention without departing from the spirit of the preferred embodiment of the present invention.

In the preferred embodiment of the present invention, the impurity concentration peak of the back gate region of the MOS transistor is formed in the deep portion of the semiconductor layer. This structure makes it possible to reduce the resistance value in the deep portion of the back gate region due to the impurity concentration, and to prevent the parasitic bipolar transistor in the MOS transistor from operating. As a result, the breakdown voltage characteristic of the MOS transistor can be improved.

In addition, in the preferred embodiment of the present invention, the appropriate threshold voltage of the MOS transistor is achieved, while the impurity concentration peak of the back gate region is formed in the deep portion of the semiconductor layer. This structure makes it possible to reduce the resistance value of the back gate region, and to prevent the parasitic bipolar transistor in the MOS transistor from operating.

Moreover, in the preferred embodiment of the present invention, the gate electrode of the MOS transistor is formed as a lamination structure with the polysilicon film and the tungsten silicon film. This structure makes it possible to form the diffusion layer as the back gate region in a desired region, thereby to reduce the device size. As a result, the on-resistance of the MOS transistor can be reduced.

Furthermore, in the preferred embodiment of the present invention, when the back gate region is formed, the back gate region is formed in the deep portion of the semiconductor layer by self-alignment using the gate electrode. This manufacturing method makes it possible to form the back gate region in a desired region, and to reduce the device size. As a result, the on-resistance per area of the MOS transistor can be reduced.

Still furthermore, in the preferred embodiment of the present invention, in the step of forming the back gate region by self-alignment using the gate electrode, the ion implantation technique is used at a highly accelerating voltage. This manufacturing method makes it possible to form the back gate region in the deep portion of the semiconductor layer, and to prevent the parasitic bipolar transistor in the MOS transistor from operating.

Yet still furthermore, in the preferred embodiment of the present invention, the gate electrode is formed by using the tungsten silicon film on the polysilicon film. This manufacturing method makes it possible to form the back gate region in a desired region by self-alignment using the gate electrode.

What is claimed is:

1. A semiconductor device comprising:
a semiconductor layer;
a drain region, a source region and a back gate region, which are formed in the semiconductor layer;
a gate oxide film formed on the semiconductor layer; and
a gate electrode formed on the gate oxide film, wherein
the source region is formed to overlap the back gate region, and
an impurity concentration peak of the back gate region is formed in a portion of the semiconductor layer deeper than a junction region between the back gate region and the source region.

2. The semiconductor device according to claim 1, wherein,
in terms of an impurity concentration of the back gate region in a vicinity of the junction region, the impurity concentration in a vicinity of a bottom surface of the source region is three times or more as high as that in a vicinity of a top surface of the source region.

3. The semiconductor device according to claim 1, wherein
the gate electrode is formed of a polysilicon film and a tungsten silicon film, and
the tungsten silicon film has a thickness greater than that of the polysilicon film.

4. A method of manufacturing a semiconductor device, comprising the steps of:
forming a gate oxide film and a gate electrode on a semiconductor layer, and then forming a back gate region in the semiconductor layer by self-alignment using the gate electrode; and
forming a source region to overlap the back gate region, and forming a drain region in the semiconductor layer; wherein,
in the step of forming the back gate region, an impurity concentration peak of the back gate region is formed in a portion of the semiconductor layer deeper than a junction region between the back gate region and the source region.

5. The method of manufacturing a semiconductor device according to claim 4, wherein, the step of forming the back gate region includes the step of performing ion implantation at an accelerating voltage of 60 to 90 (KeV).

6. The method of manufacturing a semiconductor device according to claim 4, wherein, in the step of forming the gate electrode, a tungsten silicon film is deposited on a polysilicon film, so that the tungsten silicon film has a thickness greater than that of the polysilicon film.
